(19) United States
(12) Patent Application Publication
(10) Pub. No.: US 2007/0034144 A1
(43) Pub. Date: Feb. 15, 2007

(54) OXIDE CRYSTAL GROWTH APPARATUS AND FABRICATION METHOD USING THE SAME

(76) Inventors: Akio Ogawa, Tokyo (JP); Michihiro Sano, Tokyo (JP); Hiroyuki Kato, Tokyo (JP); Hiroshi Kotani, Tokyo (JP)

Correspondence Address: CERMAK & KENEALY, LLP, 515 EAST BRADDOCK RD SUITE B, Alexandria, VA, 22314, US

(21) Appl. No.: 11/463,369

(22) Filed: Aug. 9, 2006

(30) Foreign Application Priority Data
Aug. 11, 2005 (JP) 2005-233445

(51) Int. Cl. C30B 23/00; C30B 25/00; C30B 28/12; C30B 28/14

(52) U.S. Cl. 117/95

(57) ABSTRACT

A growth apparatus and a method for making a nitrogen (N)-doped oxide crystal grow can be configured to set a nitrogen concentration to a desired concentration and to make the concentration of nitrogen uniform in a depth direction. A nitrogen source gun configured to supply ammonia (NH₃) gas into an ultrahigh vacuum chamber can be arranged on a side of an ultrahigh vacuum chamber that is approximately opposite to a side that includes an exhaust port. A stage can be located between the nitrogen source gun and the exhaust port so as to form a flow path for ammonia that allows ammonia introduced into the ultrahigh vacuum chamber to be quickly exhausted after reaching a ZnO substrate placed on the stage. As a result, accumulation of ammonia in the ultrahigh vacuum chamber can be minimized, so that the nitrogen concentration in a crystal growth layer on the ZnO substrate can be set at a desired concentration and can be made uniform in the depth direction.

This application claims the priority benefit under 35 U.S.C. § 119 of Japanese Patent Application No. 2005-233445 filed on Aug. 11, 2005, which is hereby incorporated in its entirety by reference.

### TECHNICAL FIELD

The presently disclosed subject matter relates to an oxide crystal growth apparatus and a fabrication method using the same. More particularly, the presently disclosed subject matter relates to an oxide crystal growth apparatus that can produce a ZnO compound light emitting diode (LED), a ZnO compound laser diode in a case where oxide crystals are ZnO crystals, or the like. and a fabrication method using that oxide crystal growth apparatus.

### DESCRIPTION OF THE RELATED ART

Molecular beam epitaxy (MBE) is conventionally used as a method for making crystals of zinc oxide (ZnO) grow. In this method, for example, oxygen radical beams and zinc beams emitted from a K (Knudsen) cell are simultaneously made incident on a substrate having a temperature that is increased to a crystal growth temperature, thereby depositing ZnO on the substrate. Here, the oxygen radical beams can contain oxygen radicals obtained in an electrodeless discharge tube by electromagnetic induction using an induction coil through which a high-frequency current of 13.56 MHz flows.

In the case of fabricating a light emitting device by making a ZnO thin layer grow on a substrate, one can form a p-type ZnO layer. In order to achieve this, the most dominant dopant is nitrogen (N) (see Applied Physics Letters, vol. 81, p. 1830 (2002) and Jpn. J. Appl. Phys., vol. 38, L1205 (1999), for example).

Doping of nitrogen (N) into ZnO crystals is achieved by making nitrogen radical beams from a nitrogen source gun incident on the substrate together with the zinc (Zn) and oxygen (O) beams. Here, the nitrogen radical beams can be obtained by changing nitrogen gas into nitrogen radicals.

Examples of a material gas for the nitrogen radical beams emitted from the nitrogen source gun are nitrogen dioxide (NO₂) and dinitrogen monoxide (N₂O). Ammonia (NH₃) may be emitted from the nitrogen source gun directly or after being cracked.

FIG. 1 generally shows a conventional ZnO crystal growth apparatus for making a nitrogen (N) doped ZnO crystal grow on a substrate while ammonia (NH₃) is introduced into an ultrahigh vacuum chamber.

The crystal growth apparatus includes an ultrahigh vacuum chamber 50 and a stage 51 which is supported in the ultrahigh vacuum chamber 50. A substrate 52 is placed on the stage 51. The ultrahigh vacuum chamber 50 is provided with a zinc source gun 53 for emitting zinc beams from a K cell, an oxygen source gun 54 for emitting oxygen radical beams obtained by changing oxygen gas into radicals, and a nitrogen source gun 55 for directly supplying ammonia (NH₃) gas. A ZnO crystal is caused to grow on the substrate 52 by simultaneously emitting beams from respective source guns, thereby making the beams incident at once on the substrate 52.

A reflection high energy electron diffraction (RHEED) gun 56 and a RHEED screen 57 can be attached to the ultrahigh vacuum chamber 50. In this configuration, electrons that are emitted from the RHEED gun 56 and that are diffracted from a ZnO crystal plane formed on the substrate 52 are incident on the RHEED screen 57. Due to the thus obtained diffraction image, a process of the growth and a surface structure of the ZnO crystal formed on the substrate 52 can be observed.

A nitrogen (N)-doped ZnO crystal was grown for analysis by using the ZnO crystal growth apparatus 58 shown in FIG. 1 and causing ammonia (NH₃) that is emitted from the nitrogen source gun 55 to be incident on the substrate. The grown N-doped ZnO crystal was analyzed by a secondary ion mass spectrometer (SIMS). The analysis results are shown in FIG. 2.

In FIG. 2, the abscissa represents a depth in the nitrogen (N)-doped ZnO crystal from its surface (unit: μm) and the ordinate represents a nitrogen (N) concentration (unit: atoms/cm³). From the results shown in FIG. 2, it can be seen that a ZnO crystal growth layer obtained by the above-described growth is formed from the surface (at 0 μm) to a depth of approximately 0.5 μm, and nitrogen (N) is doped into the ZnO crystal by introduction of ammonia (NH₃).

It can also be seen that the doped nitrogen (N) concentration is not uniform in a depth direction. This means that the amount of nitrogen (N) taken into the ZnO crystal growth layer changes with growth time in spite of keeping various growth conditions, including the incident amount of the zinc (Zn) and oxygen (O) beams, the supply amount of ammonia (NH₃), and substrate temperature, constant.

Therefore, under this situation, it is difficult or impossible to set the nitrogen (N) concentration in the ZnO crystal growth layer to a desired concentration even if the growth conditions are precisely controlled. It is also difficult to ensure good reproducibility when the growth is repeated.

It is considered that such a situation is specific to a crystal growth method in which oxygen (O) and ammonia (NH₃) are simultaneously supplied.

In this case, water (H₂O) molecules are generated by the reaction of oxygen (O) and hydrogen (H) obtained by decomposition of ammonia (NH₃). Furthermore, ammonia (NH₃) is accumulated in the ultrahigh vacuum chamber through intervention of the thus generated water (H₂O) molecules. The accumulated ammonia (NH₃) is taken into the ZnO crystal growth layer together with ammonia (NH₃) that is newly supplied from the nitrogen source gun, causing an increase in the amount of nitrogen (N) taken into the ZnO crystal growth layer with growth time. This is considered as the main reason why it is difficult or impossible to set the nitrogen (N) concentration in the ZnO crystal growth layer to a desired concentration.

### SUMMARY

Therefore, one aspect of the presently disclosed subject matter is to provide a nitrogen-doped oxide crystal growth apparatus that can set a nitrogen (N) concentration to a desired concentration when doping nitrogen (N) into an oxide crystal by using ammonia (NH₃) during growth of the oxide crystal.

According to another aspect of the presently disclosed subject matter, a growth apparatus can include a vacuum chamber, a substrate holder provided within the vacuum chamber, a supply unit having supply ports for supplying at least oxygen and ammonia, respectively, into a surface of a substrate in the vacuum chamber, and an exhaust unit configured to exhaust. The growth apparatus can make an oxide crystal grow while doping nitrogen into the oxide crystal. The supply unit for supplying the ammonia can be arranged on a side that is substantially opposite the side at which the exhaust port is located, such that the substrate holder is sandwiched between the ammonia supply port and the exhaust port.

In the presently disclosed subject matter, the growth apparatus can be a molecular beam epitaxy (MBE) growth apparatus. In addition, the oxide crystal may be a ZnO crystal located in the MBE growth apparatus that is configured as described above.

According to still another aspect of the presently disclosed subject matter, a fabrication method of a ZnO compound LED device includes using the above-described growth apparatus to make a p-type ZnO compound crystal grow on a growth substrate. The method can include providing the growth apparatus described above, and using the growth apparatus for growing the p-type ZnO crystal.

In the growth device of the presently disclosed subject matter, a flow of ammonia introduced from the ammonia supply unit into a vacuum chamber (for example, an ultrahigh vacuum chamber) may be quickly exhausted from the exhaust unit arranged at the opposed side after the ammonia passes the substrate. Therefore, ammonia may not be accumulated in the vacuum chamber. As a result, when doping nitrogen (N) into an oxide crystal by using ammonia (NH₃) during the growth of the oxide crystal, a nitrogen (N) concentration can be set to a desired concentration. In particular, in a case where the oxide is ZnO, the nitrogen concentration can be controlled within a preferable range when a p-type crystal layer of a ZnO compound LED device is formed.

### BRIEF DESCRIPTION OF THE DRAWINGS

These and other characteristics, features, and advantages of the disclosed subject matter will become clear from the following description with reference to the accompanying drawings, wherein:

FIG. 1 generally shows a conventional oxide crystal growth apparatus;

FIG. 2 shows a relationship between a depth of the doping of nitrogen (N) and a nitrogen concentration in compound crystals obtained by the conventional oxide crystal growth apparatus;

FIG. 3 is a schematic view of an exemplary embodiment of an oxide crystal growth apparatus made in accordance with principles of the presently disclosed subject matter;

FIG. 4 shows a relationship between a depth of doping of nitrogen (N) and a nitrogen concentration in a sample for comparison and a sample for evaluation;

FIG. 5 is a schematic view that shows another embodiment of an oxide crystal growth apparatus made in accordance with principles of the presently disclosed subject matter; and

FIG. 6A-D show a structure of compound crystals grown by the oxide crystal growth apparatus of FIG. 3.

### DETAILED DESCRIPTION OF EXEMPLARY EMBODIMENTS

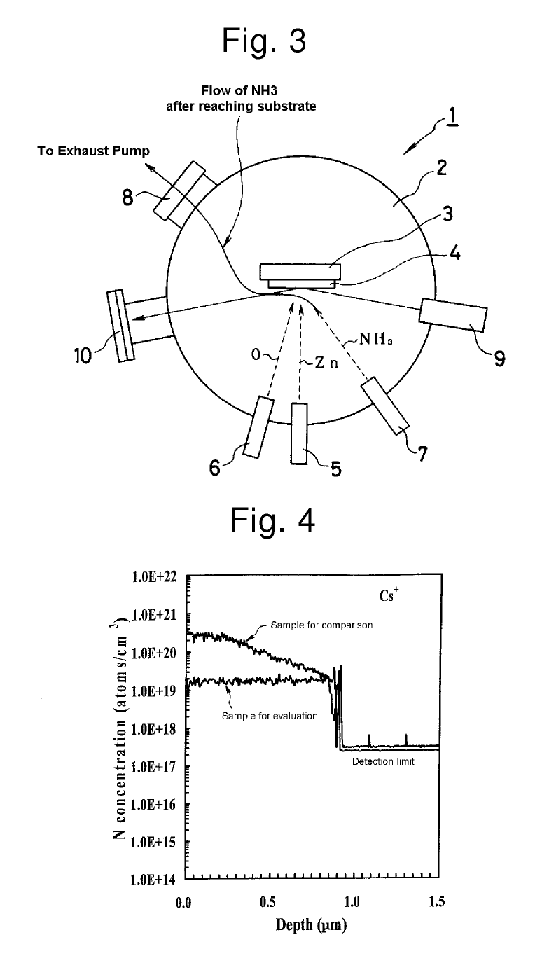

Exemplary embodiments of the presently disclosed subject matter are now described in detail with reference to FIGS. 3 to 6 (in which the same or similar components are labeled with the same reference numerals). The exemplary embodiments set forth below are specific examples of the presently disclosed subject matter and therefore include various technical features. However, it should be noted that the scope of the presently disclosed subject matter is not limited to these exemplary embodiments.

FIG. 3 generally shows an oxide crystal growth apparatus according to an exemplary embodiment of the presently disclosed subject matter. This exemplary embodiment provides a ZnO crystal growth apparatus. The ZnO crystal growth apparatus can be configured to include an ultrahigh vacuum chamber 2, and a stage 3 provided within the ultrahigh vacuum chamber 2 and serving as a substrate holder. A +c-plane ZnO substrate 4 can be placed on the stage 3.

The ultrahigh vacuum chamber 2 can be provided with a zinc source gun 5 configured to emit zinc beams from a K cell, an oxygen source gun 6 configured to emit oxygen radical beams obtained by changing oxygen gas into radicals (these serve as a supply unit), and a nitrogen source gun 7 configured to directly supply ammonia (NH₃) gas. The ZnO crystal growth apparatus 1 can be configured to simultaneusly project beams from the respective source guns onto the +c-plane ZnO substrate 4, thereby growing a ZnO crystal on the +c-plane ZnO substrate 4.

The nitrogen source gun 7 configured to supply ammonia (NH₃) gas can be located on a side that is substantially opposite the side of the exhaust port 8 such that the stage 3 is arranged between the nitrogen source gun 7 and the exhaust port 8. This arrangement can form a flow path for ammonia (NH₃) that allows introduced ammonia (NH₃) to be quickly exhausted after reaching the +c-plane ZnO substrate 4.

In addition to this, a reflection high energy electron diffraction (RHEED) gun 9 and a RHEED screen 10 can be provided with the ultrahigh vacuum chamber 2. In this configuration, electrons that are emitted from the RHEED gun 9 and that are diffracted by a ZnO crystal plane formed on the +c-plane ZnO substrate 4 are incident on the RHEED screen 10. Using the thus obtained diffraction image, one can observe a process of the layer growth and a surface structure of the ZnO crystal formed on the +c-plane ZnO substrate 4.

<Sample for Comparison>

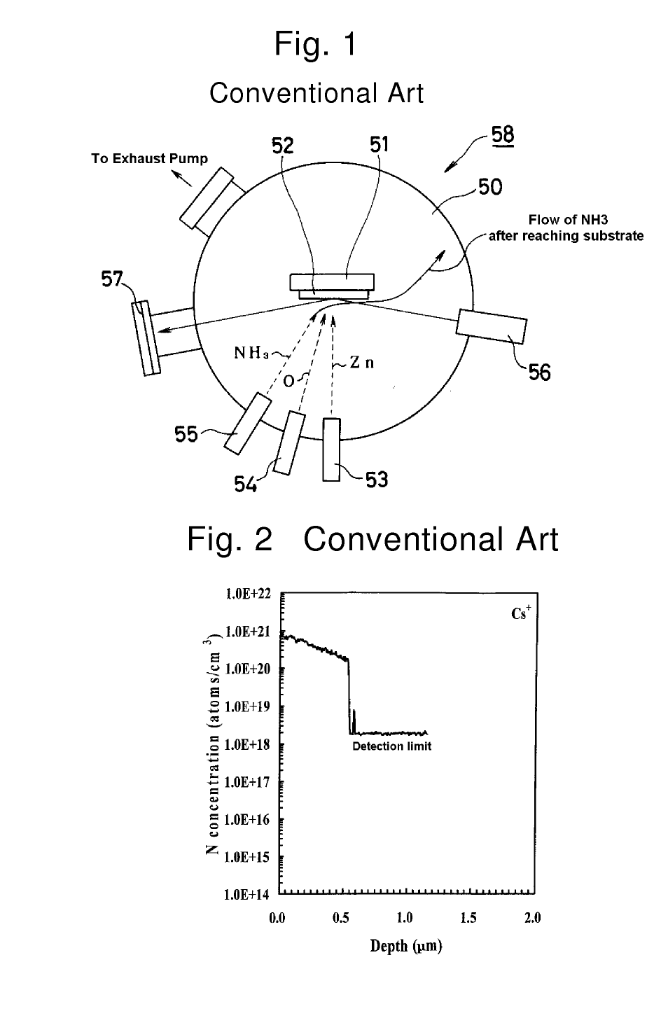

A sample for comparison was fabricated by making a nitrogen (N)-doped ZnO layer grow on a +c-plane ZnO substrate using the conventional ZnO crystal growth apparatus 58 shown in FIG. 1. More specifically, the +c-plane ZnO substrate 52 was subjected to thermal annealing under high vacuum of 1×10⁻⁹ Torr at a temperature of 850° C. for 30 minutes to clean the +c-plane ZnO substrate 52.

Then, beams emitted from the respective source guns 53, 54, and 55 were made incident on the +c-plane ZnO substrate 52 that was kept at a temperature of 700° C. In this process, Zn beams were emitted from the zinc source gun 53 that used a K cell using 7N (99.99999%) purity Zn as a solid source with a beam amount of 2.0×10⁻⁷ Torr. As for oxygen beams, 6N (99.9999%) purity oxygen gas was introduced at a flow rate of 1 sccm to be changed into plasma. The thus obtained oxygen beams were emitted from the oxygen source gun 54 with a beam amount of 3×10⁻⁵ Torr (this was approximately the same pressure as that in the ultrahigh vacuum chamber). Ammonia (NH₃) gas was introduced from the nitrogen source gun 55 at a flow rate of 0.02 sccm. As a result, a ZnO growth layer was formed on the +c-plane ZnO substrate 52 by MBE. The ZnO crystal growth layer had good flatness and the ZnO crystal was transparent.

<Sample for Evaluation>

A sample for evaluation was fabricated by growing a nitrogen (N)-doped ZnO layer by MBE on the +c-plane ZnO substrate 4 using the ZnO crystal growth apparatus 1 of the exemplary embodiment shown in FIG. 3.

A difference between the fabrication methods for the sample for comparison and the sample for evaluation was that the position of the nitrogen source gun configured to supply ammonia (NH₃) gas in the ZnO crystal growth apparatus of the exemplary embodiment of FIG. 3 (which fabricated the sample for evaluation) was different from that in the conventional ZnO crystal growth apparatus (which fabricated the sample for comparison).

More specifically, the crystal growth apparatus used for the evaluation sample was configured such that the nitrogen source gun that was configured to supply ammonia (NH₃) gas was arranged on a substantially opposite side of the stage relative to the exhaust port, with the stage arranged between the nitrogen source gun and the exhaust port so as to form a flow path for ammonia (NH₃). The flow path enables quick exhaust of introduced ammonia (NH₃) after reaching the +c-plane ZnO substrate 4. Except for this difference, the sample for comparison and the sample for evaluation were fabricated under the same growth conditions.

FIG. 4 shows a comparative analysis of results of nitrogen (N)-doped ZnO crystal growth layers in the sample for comparison versus the sample for evaluation. The analysis was made by using a secondary ion mass spectrometer (SIMS). In FIG. 4, the abscissa represents a depth in the nitrogen (N)-doped ZnO crystal growth layer from its surface (unit: μm), and the ordinate represents a nitrogen (N) concentration (unit: atoms/cm³). It can be seen in FIG. 4 that the ZnO crystal growth layer obtained by the above-described growth is formed from the surface (at 0 μm) to a depth of approximately 0.9 μm, and nitrogen (N) is doped into the ZnO crystal by introduction of ammonia (NH₃).

The analysis of the ZnO crystal growth layer in the comparison sample reveals that the concentration of doped nitrogen (N) is not uniform in the depth direction. In other words, the amount of nitrogen (N) taken into the ZnO crystal growth layer changed with the growth time, in spite of keeping growth conditions substantially constant. The growth conditions that were kept constant include: the amount of the zinc (Zn) and oxygen (O) beams incident on the ZnO, the supply amount of ammonia (NH₃), and the substrate temperature.

It is conceivable that the comparison sample results are specific to a crystal growth method in which oxygen (O) and ammonia (NH₃) are supplied simultaneously. This may be because water (H₂O) molecules are generated by reaction of oxygen (O) and hydrogen (H) obtained by decomposition of ammonia (NH₃), and then ammonia (NH₃) is accumulated in the ultrahigh vacuum chamber through intervention of the water (H₂O) molecules. The thus accumulated ammonia (NH₃) is taken into the ZnO crystal growth layer together with ammonia (NH₃) that is newly supplied from the nitrogen source gun, thereby causing an increase in the amount of nitrogen (N) taken into the ZnO crystal growth layer with the growth time.

On the other hand, in the sample for evaluation, the analysis reveals that the concentration of doped nitrogen (N) is uniform in the depth direction. There are many possible reasons for this phenomenon, some of which are considered as follows.

Since the nitrogen source gun that is configured to supply ammonia (NH₃) gas was arranged on a side of the stage that is substantially opposite to the side of the stage at which the exhaust port is located, and the stage was thus arranged between the nitrogen source gun and the exhaust port, a flow path for ammonia (NH₃) was formed that enabled quick exhaust of ammonia (NH₃) after reaching the +c-plane ZnO substrate 4. Thus, accumulation of ammonia (NH₃) in the ultrahigh vacuum chamber was minimized or eliminated.

In the sample for evaluation, the nitrogen (N)-doped ZnO crystal layer was grown by MBE on the +c-plane ZnO substrate 4 using the ZnO crystal growth apparatus of the exemplary embodiment of FIG. 3. Crystals of ZnO compounds such as crystals of ZnMgO, ZnCdO, and ZnSO can be grown on the substrate by adding a source gun configured to emit other element(s) to the ZnO crystal growth apparatus.

In this ZnO compound crystal growth apparatus configured to make a ZnO compound crystal grow, a nitrogen source gun configured to supply ammonia (NH₃) gas can be arranged substantially opposite to the exhaust port with the stage arranged between the nitrogen source gun and the exhaust port. This configuration forms a flow path for ammonia (NH₃) that enables quick exhaust of introduced ammonia (NH₃) after the ammonia reaches the substrate, and acts to relieve accumulation of ammonia (NH₃) in the ultrahigh vacuum chamber. Therefore, it is possible to set the nitrogen (N) concentration to a desired concentration and make the nitrogen (N) concentration uniform in the depth direction in the crystal growth layer.

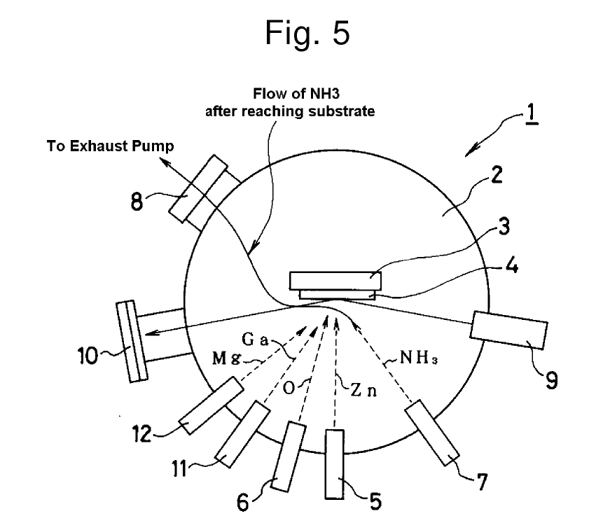

Another exemplary embodiment of a ZnO compound crystal growth apparatus according to principles of the presently disclosed subject matter can be configured as shown in FIG. 5. In this apparatus, a gallium (Ga) source gun and a magnesium (Mg) source gun are added to the ZnO crystal growth apparatus of FIG. 3. Using this apparatus, various semiconductor devices can be manufactured, such as: an LED device configured to emit short-wavelength light (for example, ultraviolet light to blue light); an LED device configured to emit white light; and applications using any of these LED devices, e.g., a lighting device, an indicator, a display, and a backlight for indicators. Furthermore, a short-wavelength diode laser can be manufactured using the principles of the disclosed subject matter.

A method for fabricating a ZnO compound LED device by using the ZnO compound crystal growth apparatus as shown in FIG. 5 is now described. In this method, the ultrahigh vacuum chamber 2 of the ZnO compound crystal growth apparatus 1 has a stage 3 on which the +c-plane ZnO substrate 4 is placed. The +c-plane ZnO substrate 4 can be dry-cleaned at 850° C. in advance. Deposition of ZnO compound can be achieved in accordance with a vapor phase growth method using MBE by making the beams from the respective source guns 5, 6, 7, 11, and 12 incident on the cleaned +c-plane ZnO substrate 4, as appropriate.

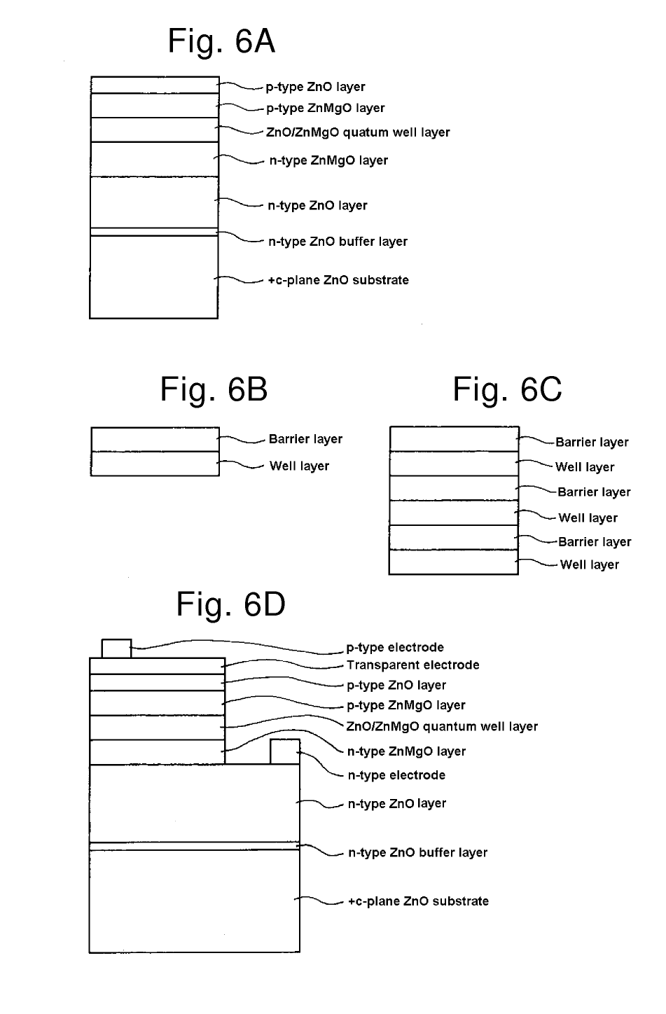

In order to facilitate the understanding of this embodiment of the fabrication method, description is made with reference to the ZnO compound crystal growth apparatus shown in FIG. 5, and the fabrication process and structure of the LED device shown in FIGS. 6A to 6D.

As shown in FIG. 6A, an n-type ZnO buffer layer is grown on the cleaned +c-plane ZnO substrate 4 at a temperature of 300° C. to 500° C. to have a thickness of 10 to 30 nm. An n-type ZnO layer in which gallium is doped with a density of 1×10¹⁸ cm⁻³ or more is grown on a surface of the n-type ZnO buffer layer at a temperature of 500° C. to 1000° C. to have a thickness of 1 to 2 μm. Then, an n-type ZnMgO layer in which magnesium is doped with a density of 1×10¹⁸ cm⁻³ or more is grown on the surface of the n-type ZnO layer at a temperature lower than the growth temperature of the n-type ZnO buffer layer and to a thickness of 100 to 600 nm. Furthermore, a ZnO/ZnMgO quantum well layer in which impurities are not doped is grown on the surface of the n-type ZnMgO layer at a temperature of 500° C. to 900° C.

The ZnO/ZnMgO quantum well layer may have a structure in which a barrier layer of ZnMgO is formed on a surface of a well layer of ZnO, as shown in FIG. 6B. Alternatively, a multiquantum well structure can be formed as shown in FIG. 6C that includes a plurality of pairs of the well layer and the barrier layer that are adjacent to each other.

On the surface of the ZnO/ZnMgO quantum well layer, a p-type ZnMgO layer in which nitrogen (N) is doped with a density of 1×10¹⁸ cm⁻³ or more can be grown at a temperature of 500° C. to 1000° C. to a thickness of 100 to 300 nm in the same growth manner as described above with respect to the fabrication of the sample for evaluation. Thus, the p-type ZnMgO layer in which nitrogen (N) is doped with a uniform density can be obtained.

Finally, a p-type ZnO layer in which nitrogen (N) is doped with a density of 1×10¹⁹ cm⁻³ or more can be grown on a surface of the p-type ZnMgO layer at a temperature of 500° C. to 1000° C. to a thickness of 100 to 200 nm in the same growth manner as described above with respect to the fabrication of the sample for evaluation. Thus, the p-type ZnO layer in which nitrogen (N) is doped with a uniform density can be obtained.

A layer formation (deposition) process using the ZnO compound crystal growth apparatus can be achieved by performing the above steps followed by an electrode formation process. In the electrode formation process, the +c-plane ZnO substrate with the layers from the n-type ZnO buffer layer to the p-type ZnO layer formed thereon is removed from the ultrahigh vacuum chamber. Then, a resist layer, a protective layer, or the like, a part of which is selectively removed, can be formed on a surface of the uppermost layer, i.e., the p-type ZnO layer. The resist layer, protective layer, or the like is/are then used as an etching mask.

Then, the layers in a region where the etching mask is removed are etched until the n-type ZnO layer is exposed by wet etching or active ion etching, for example.

An n-type electrode in which an aluminum layer having a thickness of 300 to 500 nm, for example, can be deposited on a titanium layer having a thickness of 2 to 10 nm, for example, which can then be formed on the exposed surface of the n-type ZnO layer. Then, the etching mask remaining after the formation of the cathode electrode is completely removed and a transparent electrode is formed by depositing a gold layer having a thickness of 10 nm, for example, on a nickel layer having a thickness of 0.5 to 1 nm, for example, on the surface of the p-type ZnO layer. Furthermore, a p-type electrode can be formed by depositing a gold layer having a thickness of 500 nm, for example, on the transparent electrode.

Finally, an electrode alloying treatment can be performed in an oxygen atmosphere at temperatures of 700° C. to 800° C. for 3 to 10 minutes. In this manner, the ZnO compound LED device can be fabricated.

In the above description, the presently disclosed subject matter has been described based on the exemplary embodiments. However, the presently disclosed subject matter is not limited thereto. For example, any of a −c-plane, an a-plane, or an m-plane may be used without departing from the spirit or scope of the disclosed subject matter, even though the fabrication method of the LED device using the ZnO compound crystal growth apparatus of the above described exemplary embodiments uses a +c-plane ZnO substrate. Furthermore, a sapphire substrate may be used in the method or with the apparatus of the presently disclosed subject matter.

While there has been described what are at present considered to be exemplary embodiments of the invention, it will be understood that various modifications may be made thereto, and it is intended that the appended claims cover such modifications as fall within the true spirit and scope of the invention. All conventional art references described above are herein incorporated in their entirety by reference.

What is claimed is:

1. A growth apparatus for making an oxide crystal grow while doping nitrogen into the oxide crystal, comprising:
a vacuum chamber;
a substrate holder located within the vacuum chamber;
a supply unit having supply ports configured to supply at least oxygen and ammonia respectively to a surface of a substrate in the vacuum chamber; and
an exhaust unit located adjacent a first side of the substrate holder, the exhaust unit being configured to exhaust unreacted oxygen and ammonia, wherein
the supply unit supply port that is configured to supply the ammonia is located adjacent a second side of the substrate holder, the second side of the substrate holder being substantially opposite the first side of the substrate holder such that the substrate holder is sandwiched between the supply port that is configured to supply the ammonia and the exhaust unit.

2. The growth apparatus according to claim 1, wherein the growth apparatus is configured as a molecular beam epitaxy growth apparatus.

3. The growth apparatus according to claim 1, wherein the oxide crystal is a ZnO crystal.

4. The growth apparatus according to claim 2, wherein the oxide crystal is a ZnO crystal.

5. A growth apparatus for making an oxide crystal grow while doping nitrogen into the oxide crystal, comprising:
a vacuum chamber;
a substrate holder located within the vacuum chamber;
a supply unit having at least one supply port configured to supply a raw material to a surface of a substrate in the vacuum chamber; and
an exhaust unit configured to exhaust unreacted raw material, wherein
the raw material includes at least a metal, oxygen, and nitrogen, and the supply unit includes a nitrogen supply port for supplying the nitrogen,
the nitrogen supply port being located substantially opposite to the exhaust unit with the substrate holder sandwiched between the supply port and the exhaust unit.

6. The growth apparatus according to claim 5, wherein the metal is Zn, and the nitrogen supply port is configured to supply ammonia.

7. The growth apparatus according to claim 5, wherein the growth apparatus is configured as a molecular beam epitaxy growth apparatus.

8. The growth apparatus according to claim 6, wherein the growth apparatus is configured as a molecular beam epitaxy growth apparatus.

9. The growth apparatus according to claim 5, wherein the oxide crystal is a ZnO crystal.

10. The growth apparatus according to claim 6, wherein the oxide crystal is a ZnO crystal.

11. The growth apparatus according to claim 7, wherein the oxide crystal is a ZnO crystal.

12. The growth apparatus according to claim 8, wherein the oxide crystal is a ZnO crystal.

13. A fabrication method of a ZnO compound device using the growth apparatus according to claim 1, comprising:
providing the growth apparatus according to claim 1, and a growth substrate, and
using the growth apparatus to grow a p-type ZnO compound crystal on the growth substrate.

14. The fabrication method of a ZnO compound device according to claim 13, wherein the ZnO compound device is an LED device.

15. A fabrication method of a ZnO compound device using the growth apparatus according to claim 2, comprising:
providing the growth apparatus according to claim 2, and a growth substrate, and
using the growth apparatus to grow a p-type ZnO compound crystal grow on the growth substrate.

16. The fabrication method of a ZnO compound device according to claim 15, wherein the ZnO compound device is an LED device.

17. A fabrication method of a ZnO compound device using the growth apparatus according to claim 5, comprising:
providing the growth apparatus according to claim 5, and a growth substrate, and
using the growth apparatus to grow a p-type ZnO compound crystal on the growth substrate.

18. The fabrication method of a ZnO compound device according to claim 17, wherein the ZnO compound device is an LED device.

19. A fabrication method of a ZnO compound device using the growth apparatus according to claim 6, comprising:
providing the growth apparatus according to claim 6, and a growth substrate, and
using the growth apparatus to grow a p-type ZnO compound crystal on the growth substrate.

20. The fabrication method of a ZnO compound device according to claim 19, wherein the ZnO compound device is an LED device.
